(19) United States
(12) Patent Application Publication
(10) Pub. No.: US 2026/0323885 A1
(43) Pub. Date: Oct. 15, 2026

(54) WATER CURTAIN COOLING DEVICE AND CONTAINER

(71) Applicant: CANAAN CREATIVE CO., LTD., Beijing (CN)

(72) Inventors: Guanchao Zhao, Beijing (CN); Nan Li, Beijing (CN); Shishuang He, Beijing (CN); Zonghai Chen, Beijing (CN); Xiaogang Sun, Beijing (CN); Xiaoye Zhao, Beijing (CN); He Ying, Beijing (CN); Nangeng Zhang, Beijing (CN)

(21) Appl. No.: 19/479,578

(22) PCT Filed: Mar. 7, 2024
(86) PCT No.: PCT/CN2024/080551

§ 371 Date: Oct. 28, 2025

(30) Foreign Application Priority Data
Apr. 28, 2023 (CN) 202321024269.4
May 17, 2023 (CN) 202321197472.1

(51) Int. Cl. H05K 7/20

(52) U.S. Cl. CPC H05K 7/2079; H05K 7/20172; H05K 7/20272; H05K 7/20745

(57) ABSTRACT

Provided in the present application are a water curtain cooling device and a container. The water curtain cooling device is mounted on one side of the container, and the water curtain cooling device comprises: a water curtain support frame; a water curtain set, a water inlet pipe set and a water outlet pipe set which are mounted on the water curtain support frame; and a fixing assembly which is configured to realize installation between the water inlet pipe set and the water outlet pipe set and the container. The water curtain support frame is fixed on the container in a frame type structure, the top of the water curtain support frame is provided with a plurality of water dripping holes for discharging water droplets relative to the water curtain set, the upper end of the water curtain support frame is provided with a water inlet pipe hole which is in communication with the water dripping hole, the lower end of the water curtain support frame is provided with a water outlet pipe hole for converging the water droplets, the water inlet pipe hole is in communication with the water inlet pipe set, and the water outlet pipe hole is in communication with the water outlet pipe set.

### CROSS REFERENCE TO RELATED APPLICATIONS

The present application claims priority to Chinese Patent Application No. 202321024269.4 filed on Apr. 28, 2023, and priority to Chinese Patent Application No. 202321197472.1 filed on May 17, 2023, which are incorporated herein by reference for all purposes as if fully set forth herein.

### TECHNICAL FIELD

The present application relates to the technical field of cooling technology, and more specifically, to a water curtain cooling device mounted on a container and a container provided with the water curtain cooling device.

### BACKGROUND

For containers with a large number of overloaded computing equipment mounted therein, internal temperature of the containers will be too high due to long-term overload computing when working for a long time, which will directly affect the working efficiency of the computing equipment. It is necessary to increase rapid heat dissipation and cooling, otherwise it will cause the computing equipment to work inefficiently or even cause large-scale shutdowns.

Most of the existing container cooling devices use large fans, blowers and condensing equipment. However, high-power condensing equipment consume a lot of electricity, which will significantly increase the equipment operating costs, resulting in poor economic efficiency of the computing equipment. In order to cooperate with the use of low-cost fan assemblies and achieve rapid cooling, existing containers have begun to mount water curtain cooling devices. However, due to its overly simple structure, easy to damage, and easy to increase maintenance and running costs, there is always a desire for a cooling device and a container provided with the cooling device, which can reduce power consumption, quickly cool down, have low manufacturing and use costs, be convenient for long-distance transportation without being easily damaged, and at the same time be very convenient in installation, operation and maintenance.

### SUMMARY

The technical problem to be solved by the present application is to provide a water curtain cooling device, which is capable or quickly reducing temperature within a container, consumes low power, and is easy to install.

In order to achieve the aforementioned purpose, the present application provides a water curtain cooling device, mounted on one side of a container. The water curtain cooling device includes: a water curtain support frame; a water curtain assembly, a water inlet pipe assembly, and a water outlet pipe assembly, mounted on the water curtain support frame; and a fixing assembly configured to fix on the container at least one of the water curtain support frame, the water inlet pipe assembly, and the water outlet pipe assembly.

Further, in the aforementioned water curtain cooling device, the fixing assembly includes at least one first fixing member configured to mount the water inlet pipe assembly and/or the water curtain support frame. The first fixing member is detachably mounted on at least one side of the water curtain supporting frame. The first fixing member includes a connection portion connected to the container, a connection portion connected to the water curtain support frame, a hole allowing the water inlet pipe assembly to pass through, and a bent portion for fixing the water curtain support frame.

Further, a fixing hole is opened on the aforementioned connection portion connected to the water curtain support frame, and the fixing hole cooperates with a fastener to fixedly connect the water curtain support frame.

Further, a fixing hole is provided on the aforementioned connection portion connected to the container. The fixing hole cooperates with a fastener to fixedly connect the water curtain support frame.

Further, both a fixing hole opened on the aforementioned connection portion connected to the water curtain support frame or any part of the bent portion for fixing the water curtain support frame can play the role of fixing the water curtain support frame.

Further, in the aforementioned water curtain cooling device, the fixing assembly includes at least one second fixing member configured to mount the water outlet pipe assembly and/or the water curtain support frame. The second fixing member is detachably mounted on a lower side of the water curtain support frame and/or a lower side of the container. The second fixing member includes a connection portion connected to the container and a connection portion connected to the water curtain support frame. The second fixing member has a hole allowing the water inlet pipe assembly to pass therethrough, a supporting portion allowing to fix the water outlet pipe assembly and a hole allowing wiring to pass therethrough.

Further, a fixing hole is opened in the aforementioned connection portion connected to the water curtain support frame. The fixing hole cooperates with a fastener to fixedly connect the water curtain support frame.

Further, a fixing hole is opened in the aforementioned connection portion connected to the container. The fixing hole cooperates with a fastener to fixedly connect the water curtain support frame.

Further, a fixing hole is opened in the aforementioned support portion allowing to fix the water outlet pipe assembly. The fixing hole cooperates with a fastener to fix the water outlet pipe assembly so that the water outlet pipe assembly not easy to fall off.

Further, in the aforementioned water curtain cooling device, the water curtain support frame is fixed on the container in a frame type structure; and a plurality of water dripping holes configured to discharge water droplets are provided on the top of the water curtain support frame relative to the water curtain assembly. A water inlet pipe hole in communication with the water dripping holes is provided at an upper end of the water curtain support frame, and a water outlet pipe hole for converging the water droplets is provided at a lower end of the water curtain support frame. The water inlet pipe hole is in communication with the water inlet pipe assembly, and the water outlet pipe hole is in communication with the water outlet pipe assembly.

Further, in the aforementioned water curtain cooling device, protective meshes are further mounted on a front side and/or a rear side of the water curtain support frame; the water curtain assembly is mounted between the protective meshes, or mounted on a rear side or a front side of the protective meshes.

Further, the water curtain cooling device is further mounted with dust-proof filter meshes. The dust-proof filter meshes are mounted on the container in a detachable connection manner.

Further, in the aforementioned water curtain cooling device, part of the water inlet pipe assembly is in an inverted L-shape, an F-shape or an E-shape. The water curtain support frame is provided with two water curtain assemblies arranged one above the other, and a cross-shaped window is provided on the corresponding container to form a window, such as a window in the shape of a square with a vertical divider and a horizontal divider or a rectangle with a horizontal divider, wherein each window is provided with a small water curtain assembly. Each water curtain assembly is provided with a water inlet pipe hole at an upper end, and a water outlet pipe hole at a lower end. The water inlet pipe hole is in communication with the water inlet pipe assembly, and the water outlet pipe hole is in communication with the water outlet pipe assembly. The water curtain assemblies on both vertical sides can share one water outlet pipe assembly, alternatively, each water curtain assembly is configured with one water outlet pipe assembly.

Further, in the aforementioned water curtain cooling device, the water inlet pipe assembly is further provided with a water flow regulating control valve. The water flow regulating control valve is connected to a control center. The water flow regulating control valve controls a water flow rate by controlling opening degree. On/off state of the water flow regulating control valve is linked to on/off state of a fan assembly mounted on the other side of the container. The fan assembly is connected to the control center.

In order to better achieve the aforementioned purpose, the present application further provides a container provided with the aforementioned water curtain cooling device. In some embodiments, at least one water curtain cooling device is mounted on a side wall of the container; or at least one water curtain cooling device is arranged along a length direction of the container; or at least one water curtain cooling device is arranged in an array along a length direction and a height direction of the container.

Further, in the aforementioned container, when arranged in the array, each row of water curtain cooling devices shares one water outlet pipe assembly; or at least two rows of water curtain cooling devices share one water outlet pipe assembly. The aforementioned water curtain cooling device includes: a water curtain support frame; a water curtain assembly, a water inlet pipe assembly and a water outlet pipe assembly, mounted on the water curtain support frame; and a fixing assembly configured to realize installation between the water inlet pipe assembly and the water outlet pipe assembly and the container.

Further, in the aforementioned water curtain cooling device, the water inlet pipe assembly is further mounted with a water flow regulating control valve connected to a control center. The water flow regulating control valve controls a water flow rate by controlling opening degree. On/off state of the water flow regulating control valve is linked to on/off state of a fan assembly mounted on the other side of the container. The fan assembly is connected to the control center.

Further, the aforementioned container further comprises pre-positioned mounting holes allowing to cooperate with the fan assembly and/or the cooling device for installation.

Further, a waterproof trough is provided within the container relative to a lower end of the water curtain support frame. The waterproof trough can be installed by gluing, welding, or any other fixing method.

Further, a rain shield configured to protect against rainwater is further provided above the water curtain support frame. The rain shield is detachably mounted on the container by means of a bracket. The area of the rain shield is at least larger than the cross-sectional area of the water curtain support frame and larger than the cross-sectional area of the fan assembly, so as to achieve an effective rainproof effect.

The present application further provides a container, including a fan assembly disposed on one side of the container, a cooling device disposed on the other side of the container, an assembly integrating a plurality of computing equipment mounted on an internal bracket of the container, and an electrical control cabinet electrically connected to the assembly integrating computing equipment and the fan assembly respectively, wherein the cooling device is the aforementioned water curtain cooling device. The water curtain cooling device includes: a water curtain support frame; a water curtain assembly, a water inlet pipe assembly and a water outlet pipe assembly, mounted on the water curtain support frame; and a fixing assembly configured to realize installation between the water inlet pipe assembly and the water outlet pipe assembly and the container.

Further, in the aforementioned water curtain cooling device, the water inlet pipe assembly is further mounted with a water flow regulating control valve. The water flow regulating control valve is connected to a control center. The water flow regulating control valve controls a water flow rate by controlling opening degree. On/off state of the water flow regulating control valve is linked to on/off state of a fan assembly mounted on the other side of the container, and the fan assembly is connected to the control center.

Further, the aforementioned container further comprises pre-positioned mounting holes allowing to cooperate with the fan assembly and/or the cooling device for installation.

Further, a waterproof trough is provided on a bottom layer inside the container relative to a lower end of the water curtain support frame.

Further, a rain shield configured to protect against rainwater is detachably mounted above the aforementioned container.

Further, the aforementioned fan assembly includes a fan mounting support frame and a fan sealing cover, which are detachably mounted on an exterior side of or inside the container by means of mounting holes pre-positioned on the container. The fan assembly is connected to a control center. The control center is, for example, an electrical control cabinet mounted inside the container. On/off state of the fan assembly can also be linked to on/off state of the water curtain cooling device mounted on the other side of the container.

Further, it should be noted that the aforementioned fan mounting support frame can be in a structure in the shape of a square with a vertical divider and a horizontal divider; four fans in a four-fan assembly are respectively mounted corresponding to the fan mounting support frame in a structure in the shape of a square with a vertical divider and a horizontal divider. The fan sealing cover is configured to seal a gap between the fan assembly and the fan mounting support frame. A sealant layer is further provided between the fan sealing cover, a fan assembly housing and/or the fan mounting support frame. The fan sealing cover is fixed on the fan assembly and/or the fan mounting support frame by means of a fastener. The fan sealing cover is configured to prevent rainwater from penetrating. The fan sealing cover is fixed on the fan assembly by means of a plurality of fasteners. Alternatively, the fan sealing cover is fixed on the fan mounting support frame by passing a plurality of fasteners through the fan assembly housing. Specifically, the fan sealing cover is provided with two rings of perforations, namely inner and outer rings of perforations. The inner ring of perforations cooperates with the fixed holes on the fan assembly for connection, and the outer ring of perforations cooperate with the mounting holes on the fan mounting support frame or the container for connection. There is a gap between an outer contour of the fan assembly and the fan mounting support frame or the container. A sealing plate is configured to seal the gap.

It should be noted that the container described in the present application can be regarded as a dedicated container provided with a water curtain cooling device.

The present application has a beneficial effect of achieving effective cooling of the container. Furthermore, the water curtain cooling device can be linked coordinated, and used with the fan to quickly achieve water evaporation and cooling. Still furthermore, the water curtain cooling device can cooperate with the container for installation in a very convenient manner, has strong standardization and versatility, and is easy to install and use.

The present application is described in detail below with reference to the accompanying drawings and specific embodiments, but is not intended to limit the present application.

### BRIEF DESCRIPTION OF THE DRAWINGS

FIG. 1 is a schematic structural diagram of a water curtain cooling device according to the present application;

FIG. 2 is a schematic diagram of a water curtain cooling device mounted on one side of a container according to the present application;

FIG. 3 is a schematic diagram of a support frame of a water curtain cooling device according to the present application;

FIG. 4 is a schematic diagram illustrating installation of a water inlet pipe assembly and a water outlet pipe assembly of a water curtain cooling device according to the present application;

FIGS. 5A-5C are structural diagrams of fixing members of water inlet and outlet pipe assemblies of a water curtain cooling device according to the present application;

FIG. 6A is a schematic plan view illustrating installation of dust-proof filter meshes for a water curtain cooling device according to the present application;

FIG. 6B is a sectional view of FIG. 6A taken in an A-A direction;

FIG. 7 is a schematic structural diagram of a container according to the present application;

FIG. 8 is a schematic structural diagram of a container shown in FIG. 7, with a rain shield mounted;

FIG. 9 is a schematic structural diagram of a container shown in FIG. 7, with a waterproof trough mounted;

FIG. 10 is a schematic diagram of electrical connections of a fan assembly, an electric control cabinet, and a water curtain cooling device of the container shown in FIG. 7;

FIG. 11 shows a schematic structural diagram of a container provided with a fan assembly; and

FIG. 12 is an exploded view of the structure shown in FIG. 11.

### NOTES OF REFERENCE NUMERALS

1: water curtain cooling device;
10: water curtain support frame;
11: water curtain assembly;
111: protective meshes;
12: water inlet pipe assembly;
120: water inlet pipe hole;
122: water flow regulating control valve;
13: water outlet pipe assembly;
130: water outlet pipe hole;
14: dust-proof filter meshes;
150, 150′: first fixing member;
1506, 1507, 1508, 1506′, 1508′: rigid plate;
1501, 1501′, 1502, 1504′, 1505′: hole;
1503, 1503′: bent portion;
151: second fixing member;
1516, 1517, 1518: rigid plate;
1511, 1514, 1515, 15110: hole;
1519: support portion;
2: container;
20: waterproof trough;
21: rain shield;
22: fan assembly;
220: fan mounting support frame;
221: fan sealing cover;
23: computing equipment assembly;
24: electrical control cabinet;
25: louver.

### DETAILED DESCRIPTION

The technical solution of the present application is described in detail below in conjunction with the accompanying drawings and specific embodiments to facilitate further understanding of the purpose, solution and efficacy of the present application, but it is not intended to limit the scope of protection of the claims of the present application.

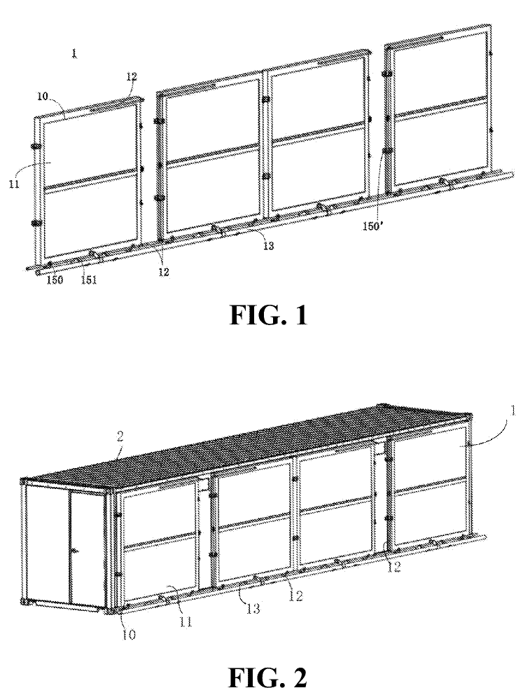

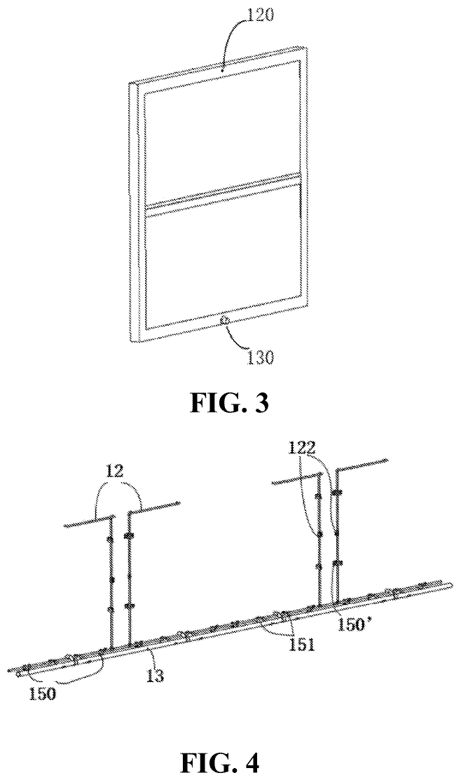

As shown in FIGS. 1-5C, an embodiment of the present application provides a water curtain cooling device 1. The water curtain cooling device 1 includes: a water curtain support frame 10; and a water curtain assembly 11, a water inlet pipe assembly 12 and a water outlet pipe assembly 13, mounted on the water curtain support frame.

In some embodiments, the water curtain cooling device 1 further includes: a fixing assembly configured to fix at least one of the water curtain support frame 10, the water inlet pipe assembly 12, and the water outlet pipe assembly 13. Exemplarily, the fixing assembly is configured to realize installation between the water inlet pipe assembly 12 and the water outlet pipe assembly 13 and the container 2. The fixing assembly includes at least one first fixing member 150/or 150′ configured to mount the water inlet pipe assembly 12 and/or the water curtain support frame 10. The first fixing member 150/or 150′ is detachably mounted on at least one side of the water curtain support frame 10. The first fixing member 150/or 150′ can also be detachably mounted on the container 2 so as to fix the water curtain support frame 10 on the container 2.

In some embodiments, the water inlet pipe assembly 12 is detachably connected to the water curtain support frame 10 and the container 2 by means of the first fixing member 150/or 150′, the water outlet pipe assembly 13 is detachably connected to the water curtain support frame 10 and the container 2 by means of a second fixing member 151.

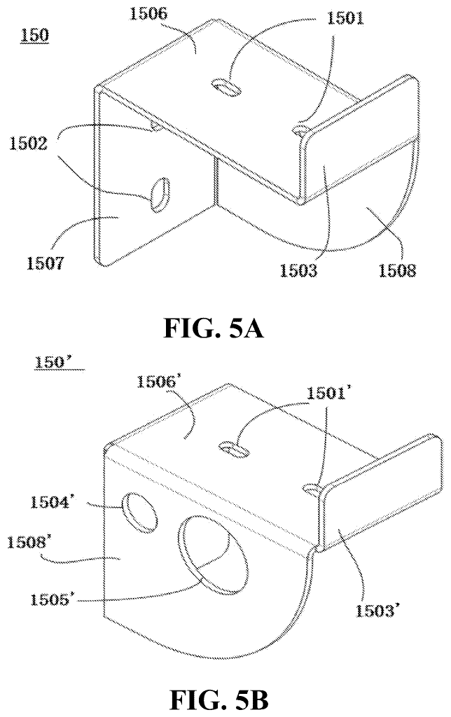

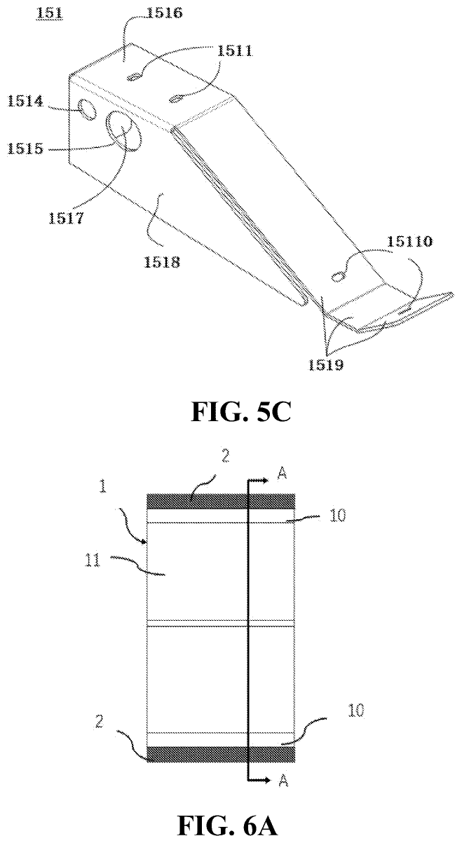

In some embodiments, the first fixing member 150/or 150′ includes a connection portion connected to the water curtain support frame 10, a connection portion connected to the container 2, a hole allowing the water inlet pipe assembly to pass therethrough, and a bent portion 1503. Exemplarily, as shown in FIGS. 5A and 5B, the connection portion connected to the water curtain support frame 10 includes a rigid plate 1506 or 1506′ and a hole 1501 or 1501′ opened therein, wherein the material of the rigid plate 1506 or 1506′ is not limited and can be a rigid material such as stainless steel capable of fixing the water curtain support frame 10. Exemplarily, as shown in FIGS. 5A and 5B, the connection portion connected to the container 2 includes a rigid plate 1507 and a hole 1502 opened therein, wherein the material of the rigid plate 1507 is the same as the material of the rigid plate 1506 or 1506′, and the rigid plate 1506 is vertically connected to the rigid plate 1507; the bent portion 1503 is vertically connected to the other side of the rigid plate 1506 in the opposite direction. The connection portion allowing the water inlet pipe assembly to pass therethrough includes a rigid plate 1508 or 1508′ and holes 1505′ and 1504′ opened therein, wherein the hole 1505′ is configured to allow the water inlet pipe assembly 12 to pass therethrough, and the hole 1504′ is configured to allow wiring (such as network cable wiring) to pass therethrough; and the first fixing member 150 has the same hole as 150′ allowing the water inlet pipe assembly 12 to pass therethrough and allowing wiring (not shown in the figures) to pass therethrough. Correspondingly, the first fixing member 150′ has the same connection portion as 150 connected to the container 2 (not shown). The rigid plate 1508 is vertically connected to the rigid plate 1506 and the rigid plate 1507 to form three mutually perpendicular surfaces, achieving the effect that the first fixing member 150 can stably fix the water inlet pipe assembly 12 on the water curtain support frame 10 and the container 2.

In some embodiments, when in use, the water inlet pipe assembly 12 passes through the hole 1505′, and the first fixing member 150 or 150′ is fixed to the water curtain support frame 10 by means of the rigid plate 1506 or 1506′ and the hole 1501 or 1501′ with fasteners (such as screws), and is fixed to the container 2 by means of the rigid plate 1507 and the hole 1502 with fasteners (such as screws) on the other side. The bent portion 1503 or 1503′ further fixes the water curtain support frame 10 on the container 2. As such, it plays the role of double fixing the water curtain support frame 10. It is worth noting that either the bent portion 1503 and the hole 1501 or 1501′ can achieve the effect of fixing the water curtain support frame 10.

In some embodiments, the fixing assembly further includes at least one second fixing member 151 configured to mount the water outlet pipe assembly 13 and/or the water curtain support frame 10. The second fixing member 151 is detachably mounted on a lower side of the water curtain support frame 10 and/or a lower side of the container 2.

In some embodiments, the second fixing member 151 includes a connection portion connected to the water curtain support frame 10, a connection portion connected to the container 2, a hole 1515 allowing the water inlet pipe assembly 12 to pass therethrough, a support portion 1519 allowing to fix the water outlet pipe assembly, and a hole 1514 allowing wiring to pass therethrough. The connection portion connected to the water curtain support frame 10 includes a rigid plate 1516 and a fixing hole 1511 opened therein, which cooperate with fasteners to fixedly connect the water curtain support frame 10. The connection portion connected to the container 2 also includes a rigid plate and a hole (not shown) opened therein, which cooperate with fasteners to be fixed on the container 2. The support portion 1519 allowing to fix the outlet pipe assembly 13 and the hole 15110 cooperate with fasteners to make the water outlet pipe assembly 13 more stable and not easy to fall off.

In some embodiments, when in use, the water inlet pipe assembly 12 passes through the hole 1515, and the water outlet pipe assembly 13 rests on the support portion 1519 and can be fixed with a fastener such as a rope or a wire through the hole 15110 opened therein. The second fixing member 151 is fixed to the water curtain support frame 10 by means of the rigid plate 1516 and the hole 1511 thereon with fasteners such as screws, and also has a rigid plate 1517 connected to the container 2 and a hole (not shown) fixable to the container 2 on the other side, which will not be repeated here. The rigid plates 1516, 1517 and 1518 are vertically connected to form three mutually perpendicular surfaces, achieving the effect that the second fixing member 151 stably fixes the water inlet pipe assembly 12 and the water outlet pipe assembly 13 on the water curtain support frame 10 or the container 2.

In some embodiments, the hole 1504′ and the hole 1514 can be configured to allow wiring, such as network cables wiring, to pass therethrough.

In some embodiments, the water curtain support frame 10 is fixed on the container 2 in a frame type structure. For example, the water curtain support frame 10 is fixed on a top side beam of the container 2, a bottom side beam of the container 2 and/or a side wall upright post of the container 2. On the interior of the top of the water curtain support frame 10, a water trough (not shown) is provided, and a plurality of water dripping holes configured to discharge water droplets are provided relative to the water curtain assembly 11. The plurality of water dripping holes are provide in the water trough at an upper end of the water curtain support frame 10. The water trough is in communication with a water inlet pipe hole 120. An inner groove (not shown) for converging the water droplets is provided on the interior of a lower end of the water curtain support frame 10. A water outlet pipe hole 130 is provided in the inner groove. The water inlet pipe hole 120 is in communication with the water inlet pipe assembly 12, and the water outlet pipe hole 130 is in communication with the water outlet pipe assembly 13.

It should be noted that part of the water inlet pipe assembly 12 can be designed to be in an inverted L shape as needed, mounted on a side surface of the container 2, and a plurality of sets of pipes can be provided according to actual needs.

In some embodiments, the water inlet pipe assembly 12 may also be configured in other shapes, such as an F shape or an E shape. The water curtain support frame 10 is provided with two water curtain assemblies 11 arranged one above the other, and a cross-shaped window is provided on the corresponding container 2 to form a window, such as a window in the shape of a square with a vertical divider and a horizontal divider or a rectangle with a horizontal divider, wherein each window is provided with a small water curtain assembly 11. Each water curtain assembly 11 is provided with a water inlet pipe hole 120 at an upper end, and is provided with a water outlet pipe hole 130 at a lower end. The water inlet pipe hole 120 is in communication with the water inlet pipe assembly 12, and the water outlet pipe hole 130 is in communication with the water outlet pipe assembly 13. The water curtain assemblies 11 on both vertical sides can share one water outlet pipe assembly 13, or each water curtain assembly 11 can be configured with one water outlet pipe assembly 13, or in other forms, which will not be repeated here.

In some embodiments, protective meshes 111 is further mounted on a front side and/or a rear side of the water curtain support frame 10, and the water curtain assembly 11 is mounted between the protective meshes 111, or mounted on a rear side or a front side of the protective meshes 111.

In some embodiments, the water inlet pipe assembly 12 is further provided with a water flow regulating control valve 122. The water flow regulating control valve 122 is connected to a control center. The control center may be, for example, an electrical control cabinet 24 mounted inside the container 2. On/off state of the water flow regulating control valve 122 is linked to on/off state of the fan assembly 22 mounted on the other side of the container 2. The water flow regulating control valve 122 controls a water flow rate by controlling opening degree. The fan assembly 22 is also connected to the control center.

In some embodiments, at least one water curtain cooling device 1 is mounted on a side wall of the container 2; or at least one water curtain cooling device 1 is arranged along a length direction of the container 2; or at least one water curtain cooling device 1 is arranged in an array along a length direction and a height direction of the container 2 (not shown).

In some embodiments, when arranged in the array, each row of water curtain cooling devices 1 shares a water outlet pipe assembly 13; or at least two rows of water curtain cooling devices 1 share a water outlet pipe assembly 13 (not shown); or other forms, which are not described in detail here.

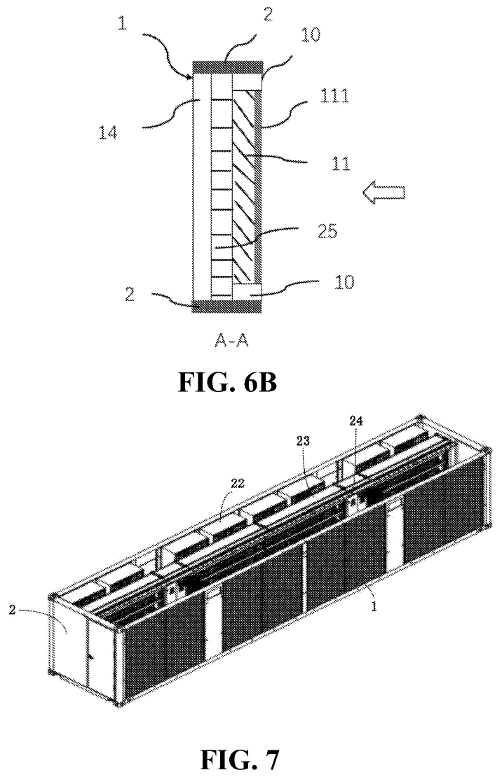

As shown in FIGS. 6A-6B, in another embodiment disclosed in the present application, a louver 25 is provided on the container 2, and dust-proof filter meshes 14 are provided behind the louver 25 close to the side of the container 2. The dust-proof filter meshes 14 include: steel meshes and a filter material (not shown). Alternatively, the dust-proof filter meshes 14 are mounted on the front side of the water curtain cooling device 1 (not shown).

In some embodiments, a waterproof trough 20 is further provided within the container 2 at the lower end of the water curtain support frame 10. The waterproof trough 20 can be installed by gluing, welding, or any other fixing method, and the present application is not limited thereto.

In some embodiments, a rain shield 21 configured to protect against rainwater is further provided above the water curtain support frame 10, and the rain shield 21 is detachably mounted on the container 2 via a bracket.

In the schematic diagrams shown in FIGS. 7-12, the present application further discloses a container 2, including: a fan assembly 22 disposed on one side of the container, detachably mounted on one side of the container 2; a cooling device arranged on the other side of the container 2; an assembly integrating a plurality of computing equipment 23 mounted on an internal bracket of the container 2; and a control center electrically connected to the computing device 23 and the fan assembly 22, respectively, wherein the control center can be, for example, an electric control cabinet 24 mounted inside the container 2; the cooling device is the aforementioned water curtain cooling device 1. The water curtain cooling device 1 can adopt the fan mounting structure described above in conjunction with FIGS. 1-5C, and its specific structure will not be repeated in the present embodiment.

In addition, in some embodiments, mounting holes (for example, blind rivet holes) are pre-positioned in the aforementioned container 2 to facilitate installation without the need for on-site drilling, thereby facilitating installation of structures such as the fan assembly 22 and the water curtain cooling device 1.

In some embodiments, a louver 25 is provided on the container 2, and dust-proof filter meshes 14 are provided behind the louver 25 close to the side of the container 2; the dust-proof filter meshes 14 include: steel meshes and a filter material (not shown). Alternatively, the dust-proof filter meshes 14 are mounted on the front side of the water curtain cooling device 1 (not shown). Alternatively, the dust-proof filter meshes 14 are mounted on the front side of the fan assembly 22 (not shown).

In some embodiments, a waterproof trough 20 is further provided on a bottom layer inside the container 2 relative to a lower end of the water curtain support frame 10. The waterproof trough 20 can be installed by gluing, welding, or any other fixing method, and the present application is not limited thereto.

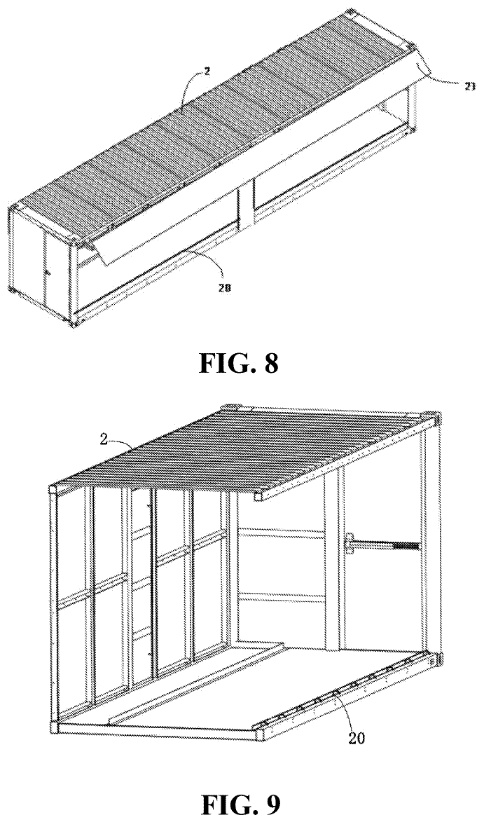

In the embodiment shown in FIG. 8, i.e., another embodiment disclosed in the present application, in this container, a rain shield 21 configured to protect against rainwater is further provided above the water curtain support frame 10 and/or above the fan assembly 22. The rain shield 21 is detachably mounted on the container 2 by means of a plurality of brackets. The area of the rain shield 21 is at least larger than the cross-sectional area of the water curtain support frame 10 and larger than the cross-sectional area of the fan assembly 22, so as to achieve an effective rainproof effect.

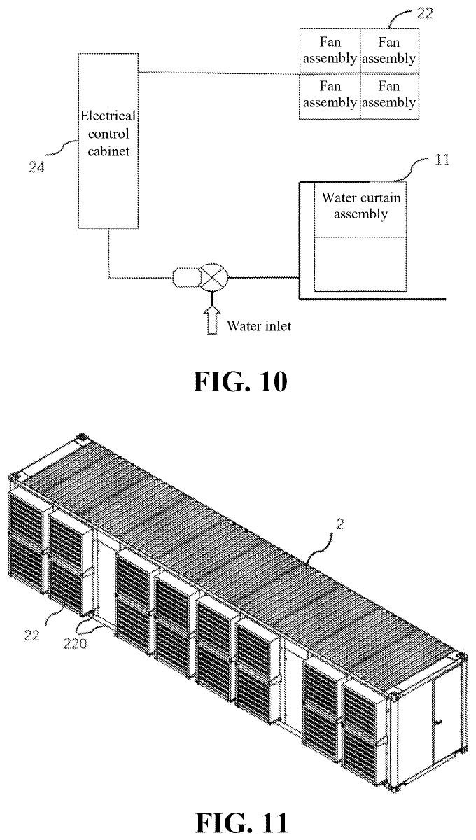

FIG. 10 shows a schematic diagram of electrical connections of a fan assembly, an electric control cabinet, and a water curtain cooling device of the container shown in FIG. 7. In the present embodiment, the electric control cabinet 24 is connected to the fan assembly 22 and can control the on and off of the fan assembly 22 and the adjustment of the rotational speed. The electric control cabinet 24 is further connected to a water pump assembly that supplies water to the water curtain assembly 11, and is configured to control the on/off or flow rate regulation of the water supply to the water curtain assembly 11.

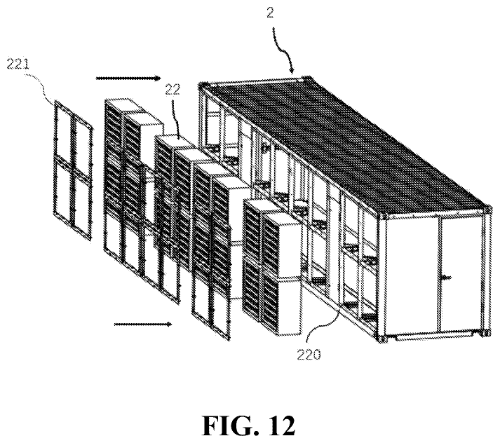

FIGS. 11-12 show schematic structural diagrams, with fan assemblies 22 mounted on one side of the container. Each fan assembly 22 includes a fan mounting support frame 220 and a fan sealing cover 221, which are detachably mounted on the exterior side of or inside the container 2 by means of pre-positioned mounting holes (not shown) on the container 2. The fan assembly 22 is connected to a control center. The control center is, for example, an electrical control cabinet 24 mounted inside the container 2. On/off state of the fan assembly 22 can also be linked to on/off state of the water curtain cooling device 1 mounted on the other side of the container 2.

It should be noted that the aforementioned fan mounting support frame 220 can be in a structure in the shape of a square with a vertical divider and a horizontal divider; four fans in a four-fan assembly 22 are respectively mounted corresponding to the fan mounting support frame 220 in a structure in the shape of a square with a vertical divider and a horizontal divider. The fan sealing cover 221 is configured to seal a gap between the fan assembly 22 and the fan mounting support frame 220. A sealant layer (not shown) is further provided between the fan sealing cover 221, the fan assembly 22 housing and/or the fan mounting support frame 220. The fan sealing cover 221 is fixed on the fan assembly 22 and/or the fan mounting support frame 220 by means of a fastener. The fan sealing cover 221 is configured to prevent rainwater from penetrating. And, the fan sealing cover 221 is fixed on the fan assembly 22 by means of a plurality of fasteners. Alternatively, the fan sealing cover 221 is fixed on the fan mounting support frame 220 by passing a plurality of fasteners through the fan assembly 22 housing. Specifically, the fan sealing cover 221 is provided with two rings of perforations, namely inner and outer rings of perforations. The inner ring of perforations cooperate with the fixed holes on the fan assembly 22 for connection, and the outer ring of perforations cooperate with the mounting holes on the fan mounting support frame 220 or the container 2 for connection. There is a gap between an outer contour of the fan assembly 22 and the fan mounting support frame 220 or the container 2. A sealing plate is configured to seal the gap.

It is worth noting that in the present embodiment, mounting holes (not shown) are pre-positioned in a frame body of the container 2. The mounting holes may be, for example, blind rivet holes to facilitate installation without the need for on-site drilling, thereby facilitating the installation of structures such as the fan assembly 22 and the water curtain cooling device 1.

### INDUSTRIAL APPLICABILITY

In summary, the water curtain cooling device of any embodiment achieves effective cooling of the container, and the water curtain cooling device is used in combination with the fan to artificially reproduce the physical process of water evaporation and cooling in nature. The power consumption is only one tenth of that of conventional air conditioners. In addition, the water curtain cooling device can cooperate with the container for installation in a very convenient manner, has strong standardization and versatility, and is easy to install and use.

The embodiments of the present application are described above in conjunction with the accompanying drawings, but the present application is not limited to the aforementioned specific implementation methods, which are merely illustrative and not restrictive. The present application may have many other embodiments. Those skilled in the art can make various corresponding changes and modifications based on the present application without departing from the spirit and essence of the present application, all of which, however, fall within the scope of protection of the claims of the present application.

1. A water curtain cooling device, mounted on one side of a container, comprising: a water curtain support frame; and a water curtain assembly, a water inlet pipe assembly, and a water outlet pipe assembly, mounted on the water curtain support frame.

2. The water curtain cooling device of claim 1, wherein the water curtain cooling device further comprises: a fixing assembly configured to fix at least one of the water curtain support frame, the water inlet pipe assembly, and the water outlet pipe assembly.

3. The water curtain cooling device of claim 2, wherein the fixing assembly comprises at least one first fixing member configured to mount the water inlet pipe assembly and/or the water curtain support frame.

4. The water curtain cooling device of claim 3, wherein the first fixing member is detachably mounted on at least one side of the water curtain support frame.

5. The water curtain cooling device of claim 3, wherein the first fixing member comprises a connection portion connected to the container and a connection portion connected to the water curtain support frame,
wherein the first fixing member further comprises a hole allowing the water inlet pipe assembly to pass therethrough, a bent portion allowing to fix the water curtain support frame. and a hole allowing wiring to pass therethrough, and
wherein a fixing hole is provided on the connection portion connected to the water curtain support frame, and the fixing hole cooperates with a fastener to securely connect the water curtain support frame.

6. (canceled)

7. The water curtain cooling device of claim 2, wherein the fixing assembly comprises at least one second fixing member configured to mount the water outlet pipe assembly and/or the water curtain support frame.

8. The water curtain cooling device of claim 7, wherein the second fixing member is detachably mounted on a lower side of the water curtain support frame and/or a lower side of the container,
wherein the second fixing member comprises a connection portion connected to the container and a connection portion connected to the water curtain support frame, and wherein the second fixing member has a hole allowing the water inlet pipe assembly to pass therethrough, a support portion allowing to fix the water outlet pipe assembly, and a hole allowing wiring to pass therethrough, and wherein a fixing hole is provided on the connection portion connected to the water curtain support frame, and the fixing hole cooperates with a fastener to securely connect the water curtain support frame.

9-11. (canceled)

12. The water curtain cooling device of claim 1, wherein the water curtain support frame is fixed on the container in a frame type structure, and a plurality of water dripping holes are provided on the top of the water curtain support frame relative to the water curtain assembly.

13. The water curtain cooling device of claim 12, wherein a water inlet pipe hole in communication with the water dripping holes is provided at an upper end of the water curtain support frame, and a water outlet pipe hole is provided at a lower end of the water curtain support frame, and wherein the water inlet pipe hole is in communication with the water inlet pipe assembly, and the water outlet pipe hole is in communication with the water outlet pipe assembly.

14. The water curtain cooling device of claim 1, wherein protective meshes are further mounted on a front side and/or a rear side of the water curtain support frame, and wherein the water curtain assembly is mounted between the protective meshes, or mounted on a rear side or a front side of the protective meshes.

15. The water curtain cooling device of claim 1, wherein the water curtain cooling device is further provided with dust-proof filter meshes mounted on the container in a detachable connection manner.

16. The water curtain cooling device of claim 1, wherein a part of the water inlet pipe assembly is in an inverted L-shape, an F-shape, or an E-shape,
wherein a plurality of water curtain assemblies are provided in the water curtain support frame, and wherein the plurality of water curtain assemblies comprise two water curtain assemblies arranged one above the other, and each of the water curtain assemblies is provided with a water inlet pipe hole at an upper end and a water outlet pipe hole at a lower end.

17-18. (canceled)

19. The water curtain cooling device of claim 1, wherein the water inlet pipe assembly is further mounted with a water flow regulating control valve connected to a control center,
wherein the water flow regulating control valve controls a water flow rate by controlling opening degree, and wherein on/off state of the water flow regulating control valve is linked to on/off state of a fan assembly mounted on the other side of the container, and the fan assembly is connected to the control center.

20-21. (canceled)

22. A container, provided with at least one water curtain cooling device of claim 1.

23. The container of claim 22, wherein the at least one water curtain cooling device is mounted on a side wall of the container.

24. The container of claim 22, wherein the at least one water curtain cooling device is arranged along a length direction of the container.

25. The container of claim 22, wherein the at least one water curtain cooling device is arranged in an array along a length direction and a width direction of the container, and wherein, when arranged in the array, each row of water curtain cooling devices shares one water outlet pipe assembly, or at least two rows of the water curtain cooling devices share one water outlet pipe assembly.

26. (canceled)

27. The container of claim 22, wherein the container further comprises pre-positioned mounting holes allowing to cooperate with the fan assembly and/or the cooling device for installation,
wherein a waterproof trough is further provided within the container relative to the lower end of the water curtain support frame, and
wherein a rain shield configured to protect against rainwater is further provided above the water curtain support frame, and wherein the rain shield is detachably mounted on the container by means of a bracket.

28-29. (canceled)

30. A container, comprising a fan assembly disposed on one side of the container, a cooling device disposed on the other side of the container, an assembly integrating a plurality of computing equipment mounted on an internal bracket of the container, and an electrical control cabinet electrically connected to the assembly integrating the computing equipment and the fan assembly, respectively, wherein the cooling device is the water curtain cooling device of claim 1.

31. The container of claim 30, wherein the container further comprises pre-positioned mounting holes allowing to cooperate with the fan assembly and/or the cooling device for installation,
wherein a waterproof trough is further provided within the container relative to a lower end of the water curtain support frame; and
wherein a rain shield configured to protect against rainwater is further provided above the water curtain support frame, and wherein the rain shield is detachably mounted on the container by means of a bracket.

32-33. (canceled)
